(19) United States
(12) Patent Application Publication
(10) Pub. No.: US 2006/0177744 A1
(43) Pub. Date: Aug. 10, 2006

(54) Method for producing a mask layout avoiding imaging errors for a mask

(76) Inventors: Christof Bodendorf, Muenchen (DE); Karin Kurth, Moritzburg (DE); Christian Meyne, Muenchen (DE); Eva Nash, Adelshofen (DE)

Correspondence Address: SLATER & MATSIL LLP, 17950 PRESTON ROAD, SUITE 1000, DALLAS, TX, 75252, US

(21) Appl. No.: 11/332,828

(22) Filed: Jan. 13, 2006

(30) Foreign Application Priority Data
Jan. 14, 2005 (DE) 10 2005 002 533.1

(51) Int. Cl. G03C 5/00; G06F 17/50; G03F 1/00

(52) U.S. Cl. 430/5; 430/311; 430/312; 430/313; 716/19; 716/21

(57) ABSTRACT

A method for producing a final mask layout (20′) avoids imaging errors. A provisional auxiliary mask layout (110) is produced, in particular in accordance with a predefined electrical circuit diagram, and is converted into the final mask layout (20′) with the aid of an OPC method. A main structure (120, 130) of the provisional auxiliary mask layout (110) is assigned optically non-resolvable auxiliary structures (160, 320). Exclusively the optically non-resolvable auxiliary structures (160, 320) are altered in the context of the OPC method, and the main structure (120, 130) itself remains unaltered.

This application claims priority to German Patent Application 10 2005 002 533.1, which was filed Jan. 14, 2005, and is incorporated herein by reference.

### TECHNICAL FIELD

The invention relates to a method for producing a mask layout that minimizes imaging errors for a mask.

### BACKGROUND

It is known that, in lithography methods, imaging errors can occur if the structures to be imaged become very small and have a critical size or a critical distance with respect to one another. The critical size is generally referred to as the “CD” value (CD: critical dimension).

What is more, imaging errors may occur if structures are arranged so closely next to one another that they mutually influence one another during the imaging. These imaging errors, based on “proximity effects,” can be reduced by modifying the mask layout beforehand with regard to the “proximity phenomena” that occur. Methods for modifying the mask layout with regard to avoiding proximity effects are referred to by experts by the term OPC methods (OPC: optical proximity correction).

FIG. 1 illustrates a lithography process without OPC correction. The illustration reveals a mask 10 with a mask layout 20 that is intended to produce a desired photoresist structure 25 on a wafer 30. The mask layout 20 and the desired photoresist structure 25 are identical in the example in accordance with FIG. 1. A light beam 40 passes through the mask 10 and also a focusing lens 50 arranged downstream and falls onto the wafer 30, thereby imaging the mask layout 20 on the wafer 30 coated with photoresist. On account of proximity effects, imaging errors occur in the region of closely adjacent mask structures with the consequence that the resulting photoresist structure 60 on the wafer 30 in part deviates considerably from the mask layout 20 and thus from the desired photoresist structure 25. The photoresist structure that results on the wafer 30, the photoresist structure being designated by reference number 60, is illustrated in enlarged fashion and schematically beneath the wafer 30 for improved illustration in FIGS. 1 and 2.

In order to avoid or to reduce these imaging errors, it is known to use OPC methods that modify the mask layout 20 beforehand in such a way that the resulting photoresist structure 60 on the wafer 30 corresponds to the greatest possible extent to the desired photoresist structure 25.

FIG. 2 shows a previously known OPC method described in the document “A little light magic” (Frank Schellenberg, IEEE Spectrum, September 2003, pages 34 to 39), which is incorporated herein by reference, in which the mask layout 20′ is altered compared with the original mask layout 20 in accordance with FIG. 1. The modified mask layout 20′ has structure alterations that are smaller than the optical resolution limit and, therefore, cannot be imaged “1:1”. These structure alterations nevertheless influence the imaging behavior of the mask, as can be discerned at the bottom of FIG. 2; this is because the resulting photoresist structure 60 corresponds distinctly better to the desired photoresist structure 25 than is the case with the mask in accordance with FIG. 1.

In the case of the previously known OPC methods by which a “final” mask layout (see, mask 20′ in accordance with FIG. 2) is formed from a provisional auxiliary mask layout (e.g., the mask layout 20 in accordance with FIG. 1), a distinction is made between so-called “rule-based” and “model-based” OPC methods.

In the case of rule-based OPC methods, the formation of the final mask layout is carried out using rules, in particular tables, defined beforehand. The method disclosed in U.S. Pat. Nos. 5,821,014 and 5,242,770, both of which are incorporated herein by reference, by way of example, may be interpreted as a rule-based OPC method, in the case of which optically non-resolvable auxiliary structures are added to the mask layout according to predetermined fixed rules, in order to achieve a better adaptation of the resulting photoresist structure (reference number 60 in accordance with FIGS. 1 and 2) to the desired photoresist structure (reference number 25 in accordance with FIGS. 1 and 2). In the case of these methods, then, a mask optimization is carried out according to fixed rules.

In model-based OPC methods, a lithography simulation method is carried out, in the course of which the exposure operation is simulated. The simulated resulting photoresist structure is compared with the desired photoresist structure, and the mask layout is varied or modified iteratively until a “final” mask layout is present, which achieves an optimum correspondence between the simulated photoresist structure and the desired photoresist structure. The lithography simulation is carried out with the aid of, for example, a DP-based lithography simulator that is based on a simulation model for the lithography process. For this purpose, the simulation model is determined beforehand by “fitting” or adapting model parameters to experimental data. The model parameters may be determined for example by evaluation of so-called OPC curves for various CD values or structure types. One example of an OPC curve is shown in FIG. 2A and will be explained in connection with the associated description of the figures. Model-based OPC simulators or OPC simulation programs are commercially available. A description is given of model-based OPC methods for example in the article “Simulation-based proximity correction in high-volume DRAM production” (Werner Fischer, Ines Anke, Giorgio Schweeger, Jörg Thiele; Optical Microlithography VIII, Christopher J. Progler, Editor, Proceedings of SPIE VOL. 4000 (2000), pages 1002 to 1009) and in the German Patent No. DE 101 33 127 C2, both of which are incorporated herein by reference.

Irrespective of whether an OPC method is a model-based or a rule-based OPC method, OPC variants can also differ with regard to their respective optimization aim. By way of example, so-called “target” OPC methods and so-called process window OPC methods, for example “defocus” OPC methods, have different optimization aims.

The aim of target OPC methods is to hit as accurately as possible the predefined target for the individual geometrical dimensions of the mask structures in the case of correctly complying with all the predefined technological and method conditions (e.g., focus, exposure dose, etc.). Thus, in the case of a target OPC variant it is assumed that all the predefined process parameters are “hit” or set and complied with in an ideal way. In this case, the term “target” is understood to mean the structure size of the main structures to be imaged.

Since the gate length of transistors is of crucial importance for their electrical behavior, target OPC methods are used in particular for the gate plane of masks. What is disadvantageous in the case of the target OPC variant, however, is that the predefined geometrical dimensions of the mask structures are actually complied with only when the predefined process parameters are complied with in a quasi exact fashion. If fluctuations in the process parameters occur, it is possible for, in some instances, considerable deviations to occur between the desired mask structures or mask dimensions and the actual resulting mask structures or mask dimensions. This may lead, for example, to a tearing away of lines or to a short circuit between lines. The resulting process window is, therefore, generally relatively small in the case of a target OPC method.

By contrast, process window OPC methods, for example defocus OPC methods, have the aim of making the process window—that is to say the permissible parameter range of the process parameters for the exposure process with the resulting mask—as large as possible in order to ensure that the mask specifications are complied with even in the case of process fluctuations. In this case, with defocus OPC methods it is accepted that the geometrical mask target dimension is not hit exactly. Deviations are, therefore, deliberately accepted in order to enlarge the process window and thus the tolerance range during later use of the mask.

A defocus OPC method is described for example in the above-mentioned German Patent No. DE 101 33 127. This method involves predefining a “fictitious” defocus value, which is taken as a basis for the simulation of the exposure operation. This defocus value specifies that the resist structure to be exposed with the mask lies somewhat outside the optimum focal plane. In the context of the OPC method, an attempt is made to achieve an optimum imaging behavior of the mask despite the defocusing purportedly present. Thus, an attempt is made to compensate for the imaging error caused by the purported defocusing. This “compensation operation” has the effect of changing the form of the mask layout in such a way that the line structures are made wider and, as well, a larger distance is produced between two adjacent line structures in each case. As a result, a mask is thus obtained with which, when using a focused exposure, the probability of the formation of wider line structures and the formation of larger distances between respectively adjacent line structures is greater than the probability of the formation of excessively small line structures and the formation of excessively small distances between adjacent line structures.

U.S. Pat. No. 6,472,108 discloses a method for providing a final mask layout. In the case of this previously known method, for the purpose of producing a final mask layout, avoiding imaging errors, for a mask, a provisional auxiliary mask layout produced—in particular in accordance with a predefined electrical circuit diagram—is converted into the final mask layout with the aid of a model-based OPC method. In the context of the OPC method, exclusively optically imagable main structures—that is to say the actual “useful structures” of the mask layout—are modified. Optically non-imagable or optically non-resolvable auxiliary structures such as scatterbars remain unaltered in the context of the OPC method.

### SUMMARY OF THE INVENTION

In one aspect, the invention specifies a method for producing a final mask layout avoiding imaging errors, which can be carried out particularly rapidly and simply.

In the case of a method of the type specified in the introduction, the method is provided for producing a final mask layout for a mask. The method generates a provisional auxiliary mask layout in accordance with a predefined electrical circuit diagram and converts the provisional auxiliary mask layout into a final mask layout with the aid of an OPC method. A main structure of the provisional auxiliary mask layout is assigned optically non-resolvable auxiliary structures wherein exclusively the optically non-resolvable auxiliary structures are altered in the context of the OPC method. The main structure itself remains unaltered.

Accordingly, it is provided, according to embodiments of the invention, that exclusively the optically non-resolvable auxiliary structures are altered in the context of the OPC method, and the main structure itself remains unaltered.

One advantage of the method according to various embodiments of the invention can be seen in the fact that a considerable process acceleration is achieved in comparison with conventional OPC methods. This is due to the fact that an alteration of the main structures and, accompanying that, a division of the main structures into segments are obviated according to embodiments of the invention. Specifically, it is precisely the division of the main structures into segments that is relatively time-consuming.

A further advantage of the method according to embodiments of the invention is that the rules for carrying out the OPC method are relatively simple. In particular, a determination of segment lengths, which would otherwise be necessary in the case of a segmentation of the main structures—as in the previously known methods—is obviated.

A third advantage of the method according to embodiments of the invention is that overall fewer “shots” are required for the definition of the critical structures during the mask writing process. In concrete terms this is likewise attributable to the omission of the segmentation of the main structures. On account of the reduction of the “shots,” there is furthermore a reduction of the potential risk of sliver formation at critical structures during the mask writing process. This will be briefly explained in more detail below.

Masks are usually written by means of individual shots in the electron beam method. These “shots” generally have either a rectangular form or a triangular form. In the case of positive mask resists, therefore, each region outside the structures has to be decomposed into such rectangles or triangles and exposed. This decomposition is carried out by means of a software and is generally not trivial in the case of complicated structures. The more complicated the structure, e.g., as a result of small projections provided as a result of an OPC correction at the structure, the more likely the risk that certain parts of the structure can only be exposed with very small rectangles. The latter remain as it were after the decomposition. These small rectangles may have very unfavorable aspect ratios. They then bear great similarity to slivers. These small rectangles can generally only be positioned with a reduced accuracy and thus contribute to a larger mask error at the structure. If, by contrast, the structure no longer has to be decomposed, it is also not possible for any slivers to arise at it.

A fourth advantage of the method according to embodiments of the invention can be seen in the fact that an overall greater accuracy is achieved during the mask writing process because potential errors on account of a segmentation of the main structures are obviated. Overall, this also results in a greater uniformity of the mask accuracy over the entire mask. The corresponding CDU value (CDU: CD uniformity value) is thus increased. The CDU value is determined by measuring the deviation of the structure (CD) on the mask from the layout target dimension. The deviation is determined at various points on the mask and the homogeneity of the deviation over the entire mask is assessed. Many shots generally lead to a poorer homogeneity on the mask.

A fifth advantage of the method according to embodiments of the invention consists in the fact that irregularities in main structures of the layout—for example so-called “jags” and “notches”—cannot impair the OPC method since the main structures themselves remain unaltered in the context of the OPC method. Accordingly, such irregularities also cannot impair the process window of the resulting mask.

A sixth advantage of the method according to embodiments of the invention consists in the reduced mask writing time and in the increased writing accuracy during mask writing processes using negative resists. Since both the structures and the auxiliary structures may be composed of simple rectangles, that is to say these are defined with only one “shot” in each case, the writing speed is increased. The accuracy is likewise increased since the position of the exposed structure edge becomes statistically less certain as the number of exposures increases.

In accordance with one advantageous refinement of the method, it is provided that a main structure of the provisional auxiliary mask layout, which main structure is oriented in a first direction at least in the region of a segment, is assigned a group of optically non-resolvable auxiliary structures running parallel to one another, and the auxiliary structures of this group, adjacent to the segment, are oriented in a second direction, which is different from the first direction. By way of example, the non-resolvable auxiliary structures may be arranged perpendicular to the main structure. A perpendicular arrangement of non-resolvable auxiliary structures is known for example from the international patent application WO 03/021 353 A1, which is incorporated herein by reference.

In order to optimize the mask layout, in the context of the OPC method, for each optically non-resolvable auxiliary structure of the group, that distance to the assigned main structure with which the respectively optimum imaging behavior of the final mask layout is achieved is preferably determined individually in each case. In other words, an optimization of the mask layout is thus achieved by virtue of the fact that non-resolvable auxiliary structures are individually arranged at a variable distance from the respective main structure.

As an alternative or in addition, the length and/or the width of the optically non-resolvable auxiliary structures of the group may also be varied in order to ensure an optimum imaging behavior of the final mask layout. Particularly in the case of semilaterally isolated main structures, it is advantageous for the length of the optically non-resolvable auxiliary structures to be chosen in a suitable manner.

With regard to the fact that the OPC method can be carried out particularly rapidly, it is regarded as advantageous if the form of the optically non-resolvable auxiliary structures of the group remains unaltered in the context of the OPC method. If rectangular or bar-shaped auxiliary structures are involved, for example, then they should maintain their rectangular form or their bar form. All that is to be varied then in such a case is the width of the rectangles or bars, the distance between the rectangles or bars of the group among one another and/or the length of the rectangles or bars.

As already mentioned, the optically non-resolvable auxiliary structures of the group may be arranged perpendicular to the longitudinal direction of the assigned main structure. As an alternative, other orientations of the non-resolvable auxiliary structures are also conceivable. By way of example, the optically non-resolvable auxiliary structures may also be arranged obliquely with respect to the longitudinal direction of the assigned main structure. By way of example, the longitudinal direction of the optically non-resolvable auxiliary structures may extend at an angle of approximately 45 degrees with respect to the longitudinal direction of the assigned main structure.

There are various embodiments regarding the configuration of the end edges of the auxiliary structures. By way of example, the end edges of the optically non-resolvable auxiliary structure may in each case run perpendicular to the longitudinal direction of the respective auxiliary structure. As an alternative, the end edges may also be oriented relative to the longitudinal direction of the assigned main structure. By way of example, the end edges may run parallel to the longitudinal direction of the respectively assigned main structure. It is also conceivable for the end edges of the optically non-resolvable auxiliary structures in each case to be formed by two end terminating edges, which taper to a point in the longitudinal direction of the auxiliary structure. In such a case, it is possible for at least one of the end terminating edges to run parallel to the longitudinal direction of the assigned main structure.

With regard to carrying out the method particularly rapidly and simply, it is preferably provided that the optically non-resolvable auxiliary structures are positioned with the aid of a simulation program.

The OPC method may, as already explained in the introduction, be carried out as a model-based OPC method or as a rule-based OPC method, whether in a target variant or a defocus variant.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows an illustration of a lithographic process without OPC correction;

FIG. 2 shows an illustration of a lithographic process with OPC correction according to the prior art;

FIG. 2A shows an illustration of the dependence of the CD value on the distance between the mask structures among one another (“OPC curve”);

FIG. 3 shows an exemplary embodiment of a first provisional auxiliary mask layout;

FIG. 4 shows an OPC method according to the prior art on the basis of the auxiliary mask layout in accordance with FIG. 3;

FIG. 5 shows a first exemplary embodiment of the method according to the invention on the basis of the auxiliary mask layout in accordance with FIG. 3;

FIG. 6 shows a second provisional auxiliary mask layout for elucidating the first exemplary embodiment of the method according to the invention;

FIG. 7 shows a second exemplary embodiment of the method according to the invention;

FIG. 8 shows a third exemplary embodiment of the method according to the invention; and

FIG. 9 shows a fourth exemplary embodiment of the method according to the invention.

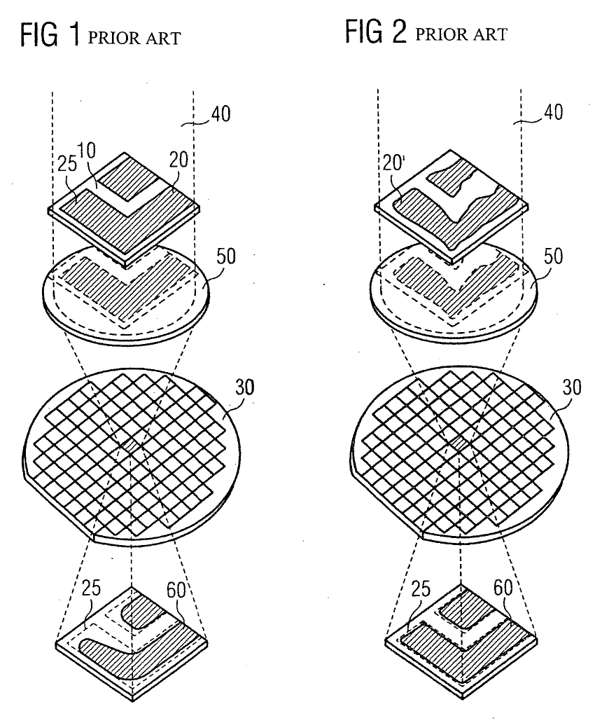

The following list of reference symbols can be used in conjunction with the figures:
10 Mask 340 Further group
20 Mask layout 350 Scatterbars
20′ Modified or final mask layout 600 Main structure
25 Photoresist structure 610 Main structure
30 Wafer 620 Longitudinal direction
40 Light beam 630 Longitudinal direction
50 Focusing lens 640 Scatterbar, non-imaging
60 Resulting photoresist structure 650 Longitudinal direction
70 OPC curve 700 End edge
71 Isolated lines 710 Terminating edge
72 Semi-dense structures 720 Terminating edge
73 Very dense structures S Point
110 Provisional auxiliary mask layout E Corner point
120 Main structure A Difference between the main structures
120′ Segmented main structure Amin Minimum distance between the main structures
130 Main structure
130′ Segmented main structure L Length of the scatterbars
140 Main structure Lmin Minimum length of the scatterbars
150 Segmentation d Distance between scatterbar/main structure
160 Scatterbars
300 Main structure dmin Minimum distance between scatterbar/main structure
310 Main structure
315 Group α Angle between longitudinal direction of scatterbar/main structure
320 Scatterbars

### DETAILED DESCRIPTION OF ILLUSTRATIVE EMBODIMENTS

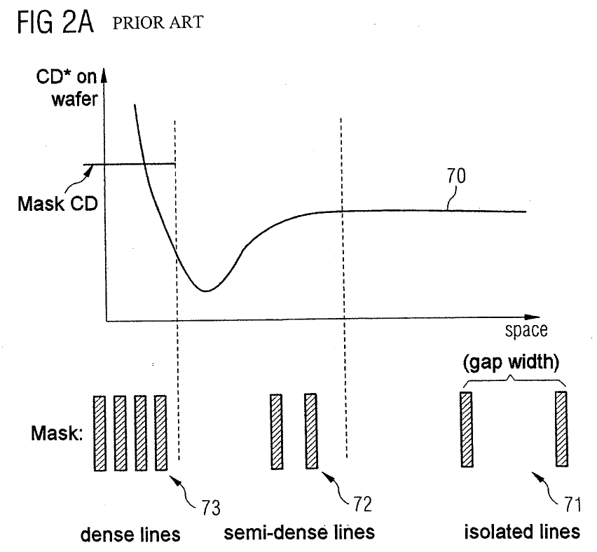

FIG. 2A illustrates an OPC curve 70 specifying how the CD values vary in a manner dependent on the distance between the main structures, for example, in the case of lines. In the case of isolated lines 71, the CD value is largely independent of the distance between the structures. In the case of average, semi-dense main structures 72, the CD value falls in the direction of smaller structure distances before it rises significantly again in the case of very dense structures 73.

In this case, the OPC curve 70 describes the CD value profile on the wafer given a constant mask CD value, which is likewise depicted in FIG. 2A for comparison.

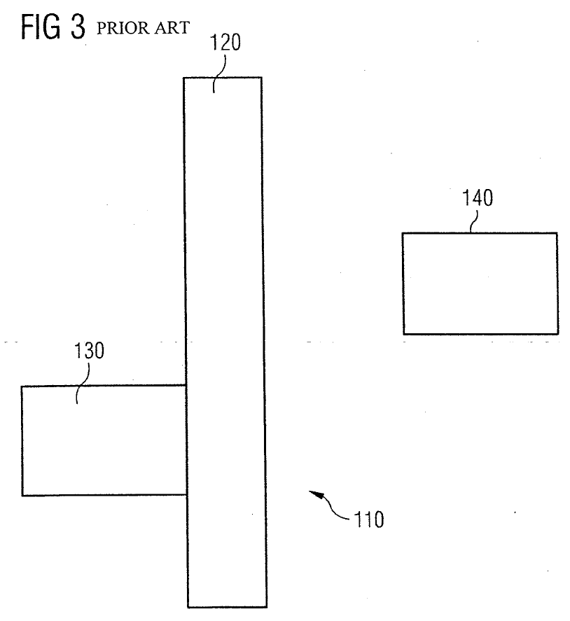

FIG. 3 reveals a provisional auxiliary mask layout 110 comprising main structures 120, 130 and 140. The three main structures 120, 130 and 140 are in each case formed by rectangles. Two main structures 120 and 130 directly adjoin one another in this case.

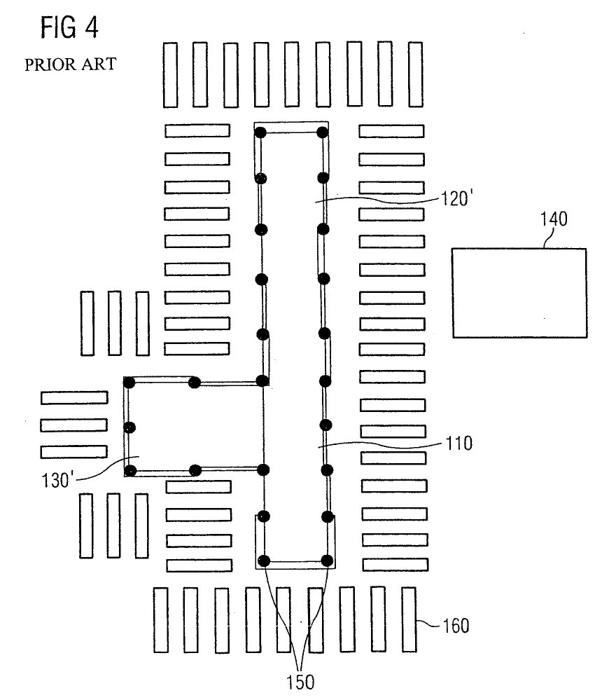

FIG. 4 shows, on the basis of the main structures 120 and 130, how the provisional auxiliary mask layout 110 in accordance with FIG. 3 is optimized according to a previously known OPC method. Firstly, the contours of the main structures 120 and 130 are segmented in a first method step, this is indicated by way of example by points 150 in FIG. 4. The two segmented main structures 120 and 130 are subsequently assigned optically non-resolvable auxiliary structures 160 in the form of scatterbars. In this case, the scatterbars 160 run perpendicular to the longitudinal extent of the respective main structures 120 and 130.

In order to generate an optimum final mask layout in which as few imaging errors as possible occur, the contours in the individual segments of the two main structures 120′ and 130′ are subsequently altered or shifted. This gives rise to modified main structures 120′ and 130′, which are different from the original main structures 120 and 130. On account of the segmentation by the segments 150, the contour profile of the main structures 120′ and 130′ is no longer rectilinear as it was originally, but rather is provided with a multiplicity of contour jumps. The further processing of the mask layout, in particular writing the mask layout onto a mask, is made more difficult by the contour jumps with the result that inaccuracies may occur under certain circumstances. Moreover, the number of “shots” required during the mask writing process is increased as a result of the occurrence of the contour jumps, with the result that the writing duration during the process of writing the final mask layout is significantly increased.

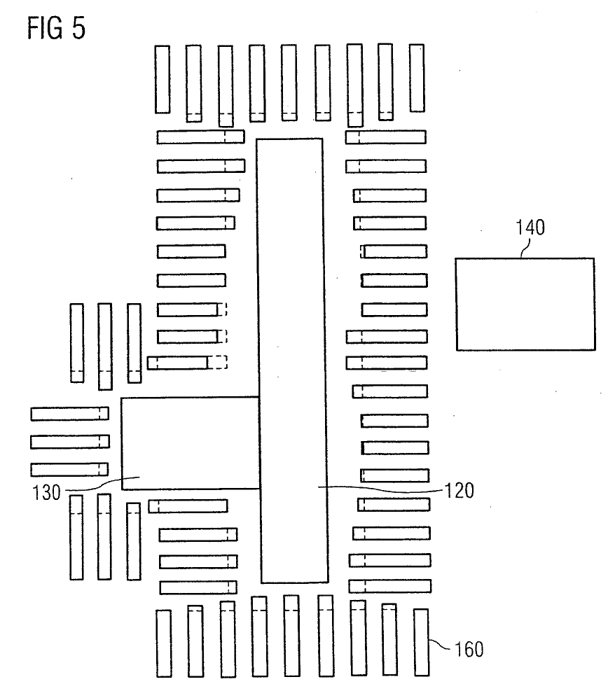

FIG. 5 shows an exemplary embodiment of the method according to the invention. It is evident that the two main structures 120 and 130 of the provisional auxiliary mask layout 110 remain unaltered. For the purpose of optimizing the layout and for the purpose of avoiding imaging errors, only the non-resolvable auxiliary structures, that is to say the scatterbars 160, are modified. In concrete terms, the scatterbars 160 are altered in terms of their length, their distance from the respectively assigned main structure or in terms of their distance relative to one another. The variation of the distance from the respectively assigned main structure and the variation of the length of the scatterbars 160 are indicated by solid lines in FIG. 5. The dashed lines show the scatterbars prior to modification.

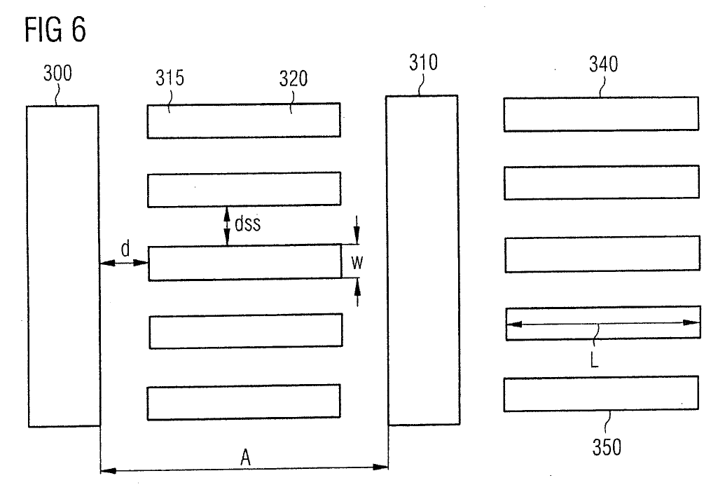

The variation of the scatterbars 160 is shown again in detail in FIG. 6. Two main structures 300 and 310 can be seen, which are at a predetermined distance A from one another. A group 315 of scatterbars 320 running parallel is arranged between the two main structures 300 and 310. The scatterbars 320 are in each case arranged perpendicular to the longitudinal extent of the two main structures 300 and 310. In order to optimize the imaging behavior of the final mask layout, the distance dss between the scatterbars 320 of the scatterbar group, the width w of each of the scatterbars and also the distance d between each scatterbar and the two main structures 300 and 310 are modified in the context of an optimization method to an extent such that a final mask layout having an optimum imaging behavior arises as the end result.

FIG. 6 furthermore shows a further group 340 having scatterbars 350, which likewise run perpendicular to the longitudinal extent of the main structure 310. Since, in FIG. 6, no further main structure is arranged to the right of the main structure 310 and the main structure 310 is accordingly semilaterally isolated, an optimization of the imaging behavior of the final mask layout is achieved by choosing the length L of the scatterbars 350 in a correspondingly optimum manner.

As can be discerned in FIGS. 5 and 6, exclusively the scatterbars are modified in the context of the OPC method. The main structures themselves remain unaltered, however.

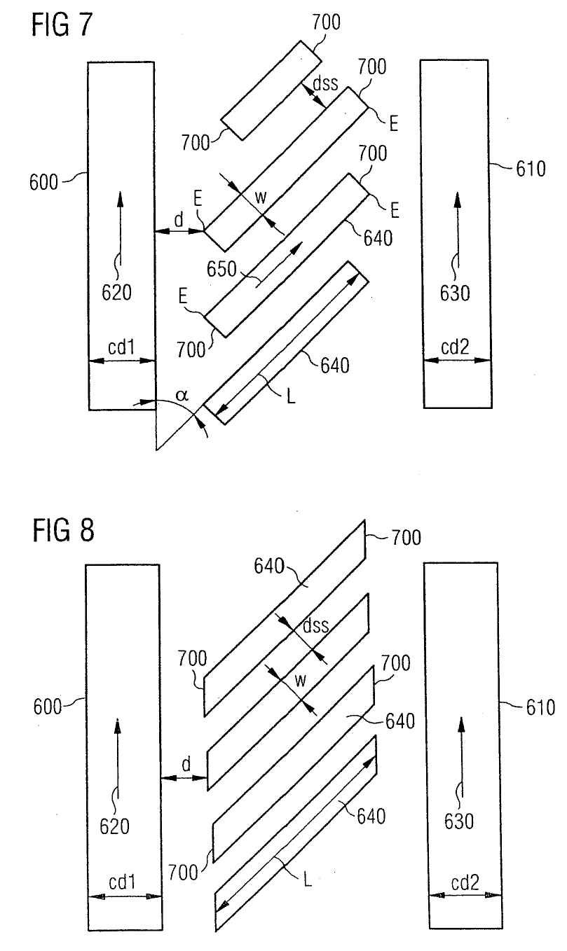

A second exemplary embodiment of the method according to the invention will now be explained with reference to FIG. 7. Two main structures 600 and 610 can be seen, the main structures being assigned auxiliary structures 640 (e.g., scatterbars). In contrast to the method in accordance with FIGS. 5 and 6, the longitudinal direction 650 of the auxiliary structures 640 extends at a predetermined angle α with respect to the longitudinal direction 620 and 630 of the main structures 600 and 610, respectively, in the case of the method in accordance with FIG. 7. The auxiliary structures 640 thus run obliquely relative to the main structures 600 and 610. The angular range of the angle α preferably lies between 10 and 80 degrees. A particularly favorable value is an angle of approximately 45 degrees.

By virtue of the oblique arrangement of the auxiliary structures 640, it is possible to choose the distance A between the main structures 600 and 610 to be smaller than is possible in the case of the method in accordance with FIGS. 5 and 6. This is because the length L no longer determines the minimum distance A between the two main structures 600 and 610. The smaller the angle α becomes, the closer the two main structures 600 and 610 can move to one another without the minimum length L of the auxiliary structure 640 constituting a limitation. In this case, a technological limit is merely defined by the minimum distance d from the respectively adjacent main structures 600 and 610.

It is evident in FIG. 7 that the end edges 700 of the auxiliary structures 640 run perpendicular to the longitudinal direction 650 of the auxiliary structures. The distance d between the auxiliary structures 640 and the main structures 600 and 610 is thus defined by the corner points E of the auxiliary structures 640.

A third exemplary embodiment of the method according to the invention will now be explained with reference to FIG. 8. In contrast to the exemplary embodiment in accordance with FIG. 7, the end edges 700 of the auxiliary structures 640 run parallel to the longitudinal direction 620 and 630 of the respectively assigned main structures 600 and 610 in the case of this exemplary embodiment. Consequently, the auxiliary structures 640 form parallelograms rather than rectangles.

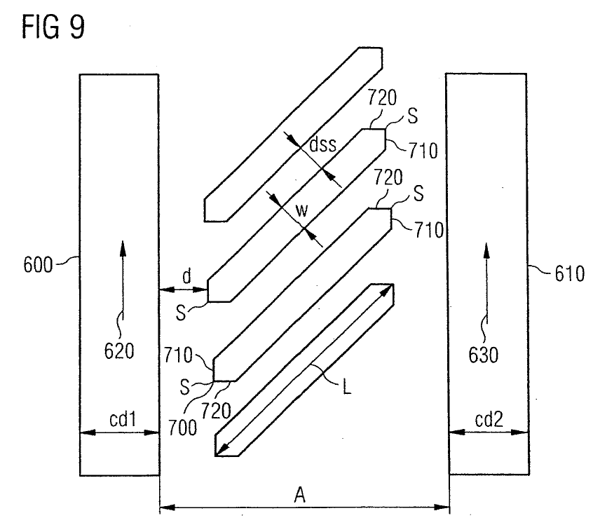

FIG. 9 shows a fourth exemplary embodiment of the method according to the invention. In the case of this fourth exemplary embodiment, the end edges 700 of the auxiliary structures 640 taper together to a point. In this case, two end terminating edges 710 and 720 respectively form a point S. In this case, one of the two end terminating edges, for example, edge 710, runs parallel to the longitudinal direction 620 and 630 of the adjacent main structures 600 and 610, respectively.

Regarding the width w of the auxiliary structures 640, the distance dss between the auxiliary structures 640 among one another and also the distance d between the auxiliary structures 640 and the respectively adjacent main structures 600 and 610, the following should be taken into account: the distance d is, in each case, to be chosen as small as possible in order that the process-window-enlarging influence of the auxiliary structures 640 is as large as possible. However, the distances d must not be too small either, since an imaging of the auxiliary structures 640 during the lithography method must always be avoided. Experience shows that the lower limit dmin for the distance d is dependent on the width w of the auxiliary structure 640 and also on the width cd1 and cd2 of the adjacent main structures 600 and 610, respectively. The smaller the width w of the auxiliary structures 640 and also the width cd1 and cd2 of the two main structures 600 and 610, respectively, the smaller the minimum distance dmin can usually be chosen. In this case, the minimum distance dmin is dependent both on the exposure process and on the mask fabrication process and generally cannot fall below a specific value for a predetermined technology. The same correspondingly holds true for the length L of the auxiliary structures 640: the length L thereof likewise usually cannot fall below a lower limit Lmin depending on the respective mask fabrication process; experience shows that the lower limit Lmin is a multiple of the minimum distance dmin and the minimum width w of the auxiliary structures 640.

In the case of an oblique arrangement of the auxiliary structures 640, the minimum distance Amin between the two main structures 600 and 610 results in accordance with the following mathematical relationship:
Amin=2*dmin+Lmin*cosα

Consequently, the smaller the angle α becomes, the more densely the two main structures 600 and 610 can move toward one another. At an angle of α=45 degrees, this therefore results in a minimum distance Amin of:
Amin=2*dmin+Lmin/√2

What is claimed is:

1. A method for producing a final mask layout for a mask, the method comprising:
generating a provisional auxiliary mask layout in accordance with a predefined electrical circuit diagram; and
converting the provisional auxiliary mask layout into a final mask layout with the aid of an OPC method, a main structure of the provisional auxiliary mask layout being assigned optically non-resolvable auxiliary structures wherein:
exclusively the optically non-resolvable auxiliary structures are altered in the context of the OPC method; and
the main structure itself remains unaltered.

2. The method as claimed in claim 1, wherein
a main structure of the provisional auxiliary mask layout, which main structure is oriented in a first direction at least in the region of a segment, is assigned a group of optically non-resolvable auxiliary structures running parallel to one another; and
the auxiliary structures of the group, adjacent to the segment, are oriented in a second direction, which is different from the first direction.

3. The method as claimed in claim 2, wherein, in the context of the OPC method, for each optically non-resolvable auxiliary structure of the group, that distance to the assigned main structure with which the respectively optimum imaging behavior of the final mask layout is achieved is determined individually in each case.

4. The method as claimed in claim 2, wherein the distance between the optically non-resolvable auxiliary structures of the group relative to one another is varied in the context of the OPC method.

5. The method as claimed in claim 1, wherein the form of the optically non-resolvable auxiliary structures remains unaltered in the context of the OPC method.

6. The method as claimed in claim 1, wherein the optically non-resolvable auxiliary structures have a rectangular, parallelogram or bar form.

7. The method as claimed in claim 1, wherein the length of the optically non-resolvable auxiliary structures is varied in the case of a semilaterally isolated main structure.

8. The method as claimed in claim 1, wherein the width of the optically non-resolvable auxiliary structures is varied.

9. The method as claimed in claim 1, wherein a group with the optically non-resolvable auxiliary structures is arranged in such a way that the longitudinal direction of the auxiliary structures extends perpendicular to the longitudinal direction of the assigned main structure.

10. The method as claimed in claim 1, wherein a group with the optically non-resolvable auxiliary structures is arranged in such a way that the longitudinal direction of the auxiliary structures extends obliquely with respect to the longitudinal direction of the assigned main structure.

11. The method as claimed in claim 1, wherein the optically non-resolvable auxiliary structures are arranged in such a way that the longitudinal direction of the auxiliary structure and the longitudinal direction of the assigned main structure are at an angle of 45 degrees with respect to one another.

12. The method as claimed in claim 1, wherein at least one end edge of the optically non-resolvable auxiliary structures runs perpendicular to a longitudinal direction of the respective auxiliary structure.

13. The method as claimed in claim 1, wherein at least one end edge of the optically non-resolvable auxiliary structures runs parallel to a longitudinal direction of the assigned main structure.

14. The method as claimed in claim 1, wherein at least one end edge of the optically non-resolvable auxiliary structures is formed by two end terminating edges which taper to a point in a longitudinal direction of the respective auxiliary structure.

15. The method as claimed in claim 14, wherein at least one of the end terminating edges runs parallel to a longitudinal direction of the assigned main structure.

16. The method as claimed in claim 1, wherein the optically non-resolvable auxiliary structures are positioned with the aid of a simulation program.

17. The method as claimed in claim 1, wherein a model-based OPC method or a rule-based OPC method is carried out as the OPC method.

18. The method as claimed in claim 1, wherein a target OPC method or a defocus OPC method is carried out as the OPC method.

19. A method of making a semiconductor device, the method comprising:
generating a final mask layout by generating a provisional auxiliary mask layout in accordance with a predefined electrical circuit diagram and converting it into a final mask layout with the aid of an OPC method, a main structure of the provisional auxiliary mask layout being assigned optically non-resolvable auxiliary structures wherein:
exclusively the optically non-resolvable auxiliary structures are altered in the context of the OPC method; and
the main structure itself remains unaltered;
fabricating a mask using the final mask layout;
coating a resist on a semiconductor wafer;
irradiating the resist through the mask; and
changing a layer at the upper surface of the semiconductor wafer in accordance with a pattern from the mask.

20. The method as claimed in claim 19, wherein
a main structure of the provisional auxiliary mask layout, which main structure is oriented in a first direction at least in the region of a segment, is assigned a group of optically non-resolvable auxiliary structures running parallel to one another; and
the auxiliary structures of the group, adjacent to the segment, are oriented in a second direction, which is different from the first direction.
